(19) United States
(12) Patent Application Publication
(10) Pub. No.: US 2025/0167777 A1
(43) Pub. Date: May 22, 2025

(54) Device and Method for Signal Retiming

(71) Applicant: Microsemi SOC Corp., Chandler, AZ (US)

(72) Inventors: Barry Britton, Slatington, PA (US); Peter Stinson, Wind Gap, PA (US); Keklik Alptekin, San Jose, CA (US); Brian Moeller, Coplay, PA (US)

(73) Assignee: Microsemi SOC Corp., Chandler, AZ (US)

(21) Appl. No.: 18/903,799

(22) Filed: Oct. 1, 2024

Related U.S. Application Data
(60) Provisional application No. 63/601,380, filed on Nov. 21, 2023.

(51) Int. Cl. H03K 5/131; H03K 5/00; H03K 5/05; H03K 5/06; H03K 5/133; H03K 5/135

(52) U.S. Cl. CPC H03K 5/131; H03K 5/05; H03K 5/06; H03K 5/133; H03K 5/135; H03K 2005/00058

(57) ABSTRACT

A device and method is provided with a first portion of the device in communication via a data line with a second portion of the device, an retiming circuit to receive a first clock from the first portion of the device and a second clock from the second portion of the device; and introduce a delay value in the second clock to generate a delayed clock; and a validation circuit to receive a data value arriving at the first portion of the device; capture a first sample of the data value sampled with the first clock; capture a second sample of the data value sampled with the delayed clock; and compare the first sample with the second sample.

### RELATED APPLICATIONS

This application claims priority to U.S. provisional application Ser. No. 63/601,380, filed on Nov. 21, 2023, the disclosure of which is incorporated by reference in its entirety for all purposes.

### FIELD OF THE INVENTION

The present disclosure relates to devices and methods for retiming signals, more specifically for retiming signals in an integrated circuit.

### BACKGROUND

In certain chip designs, there are cases where a block generates data with a clock-forwarded architecture. In some examples, a chip may include a microcontroller, an application specific integrated circuit (ASIC) portion, and/or a programmable portion. In some examples, the programmable portion may be field programmable, e.g., a field programmable gate array. In some cases, due to the placement of blocks in the design, the clock routing delays between a circuit block (sometimes referred to as an intellectual property or “IP” block) that generates its own clock and the IP data path can be very high, with a maximum amount that can be larger than 1.25 times the fastest clock period supported. In addition, these delays can be variable depending on process, voltage, and temperature.

There is a need for a retiming circuit which may delay a clock signal to match delays in a datapath and to track changes in delays over process, voltage, and temperature.

### SUMMARY

In some examples, a device comprises a first portion of the device in communication via a data line with a second portion of the device, an retiming circuit to receive a first clock from the first portion of the device and a second clock from the second portion of the device; and introduce a delay value in the second clock to generate a delayed clock; and a validation circuit to receive a data value arriving at the first portion of the device; capture a first sample of the data value sampled with the first clock; capture a second sample of the data value sampled with the delayed clock; and compare the first sample with the second sample. In some examples, in a calibration mode, the validation circuit is to identify a minimum delay value wherein the validation circuit determines no mismatch based on the comparison of the first sample with the second sample, identify a maximum delay value wherein the validation circuit determines no mismatch based on the comparison of the first sample with the second sample, select an intermediate delay value between the minimum delay value and the maximum delay value. In some examples, the intermediate delay value is centered between the minimum delay value and the maximum delay value. In some examples, the intermediate delay value is offset by a configurable offset setting from the center between the minimum delay value and the maximum delay value. In some examples, the validation circuit is to, in an operational mode, determine a mismatch based on the comparison of the first sample with the second sample; modify the delay value; receive a subsequent data value arriving at the first portion of the device; capture a first sample of the subsequent data value sampled with the first clock; capture a second sample of the subsequent data value sampled with the delayed clock; and determine no mismatch based on a comparison of the first sample of the subsequent data value and the second sample of the subsequent data value. In some examples, the validation circuit is to, in a calibration mode, generate a test pattern to sequentially set the data value arriving at the first portion of the device. In some examples, the validation circuit is to, in a calibration mode, select a line of a data bus between the first portion of the device and the second portion of the device to obtain the data value arriving at the first portion of the device. In some examples, in a calibration mode, the validation circuit is to set the delay to a next delay value; set a subsequent data value arriving at the first portion of the device; capture a first sample of the subsequent data value sampled with the first clock; capture a second sample of the subsequent data value sampled with the delayed clock; and determine no mismatch based on a comparison of the first sample of the subsequent data value and the second sample of the subsequent data value; add a data skew amount of time to the delay; and exit the calibration mode. In some examples, the delay value specifies a specific delay circuit path.

In some examples, a device is provided that includes a first clock; an retiming circuit to generate a delayed clock from a second clock; and a validation circuit including a data input; a first sample memory coupled to the data input, the first sample memory to sample the data input, the first sample memory to sample the data input with the first clock; a second sample memory coupled to the data input, the second sample memory to sample the data input with the delayed clock; and a comparing circuit to compare an output of the first sample memory with an output of the second sample memory. In some examples, the validation circuit is, in a calibration mode, to generate a test pattern to sequentially set a data value on the data input. In some examples, the validation circuit is to, in a calibration mode, select a delay value by changing an input to a delay selection circuit within the retiming circuit; set a subsequent data value on the data input; receive the subsequent data value at the first sample memory clocked with the first clock; receive the subsequent data value at the second sample memory clocked with the delayed clock; determine no mismatch by comparing the output of the first sample memory with the output of the second sample memory; and exit the calibration mode. In some examples, the delay selection circuit selects a specific delay circuit path comprising at least one of an inverter, a coarse delay component, and a fine delay component. In some examples, the validation circuit is to, in the calibration mode, identify a minimum delay selection for which the validation circuit determines no mismatch by comparing the output of the first sample memory with the output of the second sample memory; identify a maximum delay selection for which the validation circuit determines no mismatch by comparing the output of the first sample memory with the output of the second sample memory; and select an intermediate delay value between the minimum delay value and the maximum delay value. In some examples, the validation circuit is to, in an operational mode, determine a mismatch by comparing the output of the first sample memory with the output of the second sample memory; and modify the input to the delay selection circuit to select a different amount of delay.

In some examples, a method is provided comprising receiving a first clock from a first portion of a semiconductor device and a second clock from a second portion of the semiconductor device; introducing a delay in the second clock to generate a delayed clock delayed by a specified delay value; receiving a data value arriving at the first portion of the semiconductor device; capturing a first sample of the data value sampled with the first clock; capturing a second sample of the data value sampled with the delayed clock; and comparing the first sample with the second sample. In some examples, the method includes generating a test pattern to sequentially set the data value arriving at the first portion of the semiconductor device. In some examples, the method includes selecting a line of a data bus connecting the first portion of the semiconductor device to the second portion of the semiconductor device to obtain the data value arriving at the first portion of the semiconductor device. In some examples, the method includes setting the specified delay value to a next delay value; setting a new data value arriving at the first portion of the semiconductor device; determining no mismatch by comparing a first sample of the new data value sampled with the first clock with a second sample of the new data value sampled with the delayed clock; and exiting the calibration mode. In some examples, the specified delay value specifies a specific delay circuit path. In some examples, the method includes identifying a minimum delay value for which the captured first sample equals the captured second sample; identifying a maximum delay value for which the captured first sample equals the captured second sample; determining an intermediate delay value between the minimum delay value and the maximum delay value; and setting the specified delay value to the intermediate delay value. In some examples, the method includes determining a mismatch by comparing the captured first sample and the captured second sample; modifying the specified delay value; receiving a subsequent data value arriving at the first portion of the semiconductor device; capturing a first sample of the subsequent data value sampled with the first clock; capturing a second sample of the subsequent data value sampled with the delayed clock; and determining no mismatch based on a comparison of the first sample of the subsequent data value and the second sample of the subsequent data value.

### BRIEF DESCRIPTION OF THE FIGURES

FIG. 1 illustrates one of various examples of a delay circuit.

FIG. 2 illustrates one of various examples of a retiming circuit to retime a clock signal in a receive path.

FIG. 3 illustrates one of various examples of a retiming circuit to retime a clock signal in a transmit path.

FIG. 4 illustrates one of various examples of a retiming circuit.

FIG. 5 illustrates one of various examples of a retiming circuit.

FIG. 6 illustrates one of various examples of a relationship between an IP clock, a fabric clock and a gib clock.

FIG. 7 illustrates one of various examples of a device with an retiming circuit and a calibration circuit.

FIG. 8 illustrates one of various examples of a method for validating a delay in an integrated circuit device.

FIG. 9 illustrates one of various examples of a method for adjusting a delay in an integrated circuit device.

FIG. 10 is a timing diagram illustrating timing of various data lines according to certain examples of the present disclosure.

FIG. 11 illustrates delay coverage by clock period, according to certain examples of the present disclosure.

FIG. 12 illustrates one of various examples of a delay circuit.

### DETAILED DESCRIPTION

Examples of the present disclosure aim to calibrate and validate a clock delay circuit so as to adjust the clocking of data communicated between two portions of a circuit. Aspects of certain examples are described with reference to individual figures.

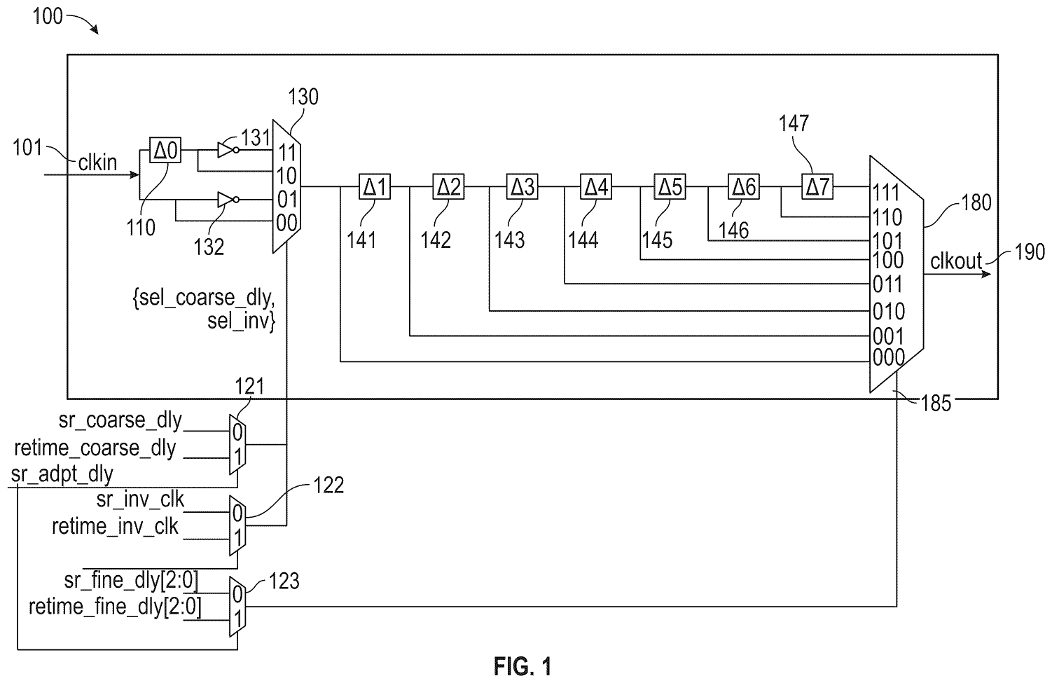

FIG. 1 illustrates one of various examples of a variable delay circuit 100, which may be used as an retiming circuit to align clock signals. Clock input 101 may be input to delay circuit 100. Coarse delay circuit 110 may apply a fixed delay to clock input 101. Inverter 131 may invert the output of coarse delay circuit 110 resulting in substantially greater than one half-cycle delay. Inverting a clock signal introduces approximately one-half cycle delay because the rising edge of the clock is translated into a falling edge and the next rising edge does not occur until another half-cycle later (plus any internal delay within the inverter). Inverter 132 may invert clock input 101, which can introduce a half-cycle delay. Multiplexer 130 may select one of four inputs: clock input 101, the output of inverter 132, the output of coarse delay circuit 110, or the output of inverter 131. In some examples, coarse delay circuit 110 may introduce approximately 1000 ps of delay.

Multiplexer 121 may select a coarse delay. Multiplexer 122 may select an inverted clock. The output of multiplexer 121 and the output of multiplexer 122 may comprise the select input of multiplexer 130. Multiplexer 130 may select between four clocks based on clk_in 101 with different delay characteristics. Multiplexer 130 is controlled by two bits that select a combination of coarse delay and inversion (which generates a half phase delay). An input to multiplexer 130 of {0,0} selects the clkin 101 without modification. An input of {0,1} selects the inverted clkin 101. An input of {1,0} selects clkin 101 delayed by coarse delay 110. An input of {1,1} selects clkin 101 delayed by coarse delay 110 and inverted by inverter 131. Multiplexers 121, 122, and 123 may be switched from one set of delay settings to another by modifying the signal to implement an adaptive delay, e.g., sr_adpt_dly. Configuration values with a prefix of “sr_” may be fed from a register of stored configuration values, e.g., a register storing the delay settings determined in an active delay calibration process as described herein. Configuration values with a prefix of “Retime_” may be provided by user installed software running on a microcontroller.

The output of multiplexer 130 may be input to a chain of fine delay circuits 141, 142, 143, 144, 145, 146 and 147. In some examples, fine delay increments may be approximately 125 ps. Respective fine delay circuits 141, 142, 143, 144, 145, 146 and 147 may introduce a fixed delay between the input and output. Respective fine delay circuits may introduce the same respective delay or may introduce a different respective delay value.

One of skill in the art will appreciate that delay circuit 100 could be modified to provide other arrangements of delay elements that would provide a controllable delay suitable for the present disclosure. One of skill in the art will also appreciate that delay circuit 100 could be modified to allow for different control inputs to translate into a selection of an amount of delay. For example, a numeric delay value could be decoded into a suitable combination of inverters, coarse delay elements, and fine delay elements. In one approach, a numeric delay value could be used to lookup selections in a table that most closely approximates the delay expressed in the numeric delay value.

FIG. 1 illustrates a delay circuit 100 with 7 fine delay circuits, but this is not intended to be limiting. Other examples may include fewer fine delay circuits or may include more fine delay circuits.

Multiplexer 180 may select one of the fine delay circuit outputs or the output of multiplexer 130, presented at a respective one of the inputs of multiplexer 180 and generate clock output 190 by passing the selected one of the input of multiplexer 180 to the output of multiplexer 180. Multiplexer 123 may provide the select signal 185 to multiplexer 180. In some examples, a delay value may be translated into a set of inputs to multiplexer 130 and multiplexer 185 to specify a delay circuit path.

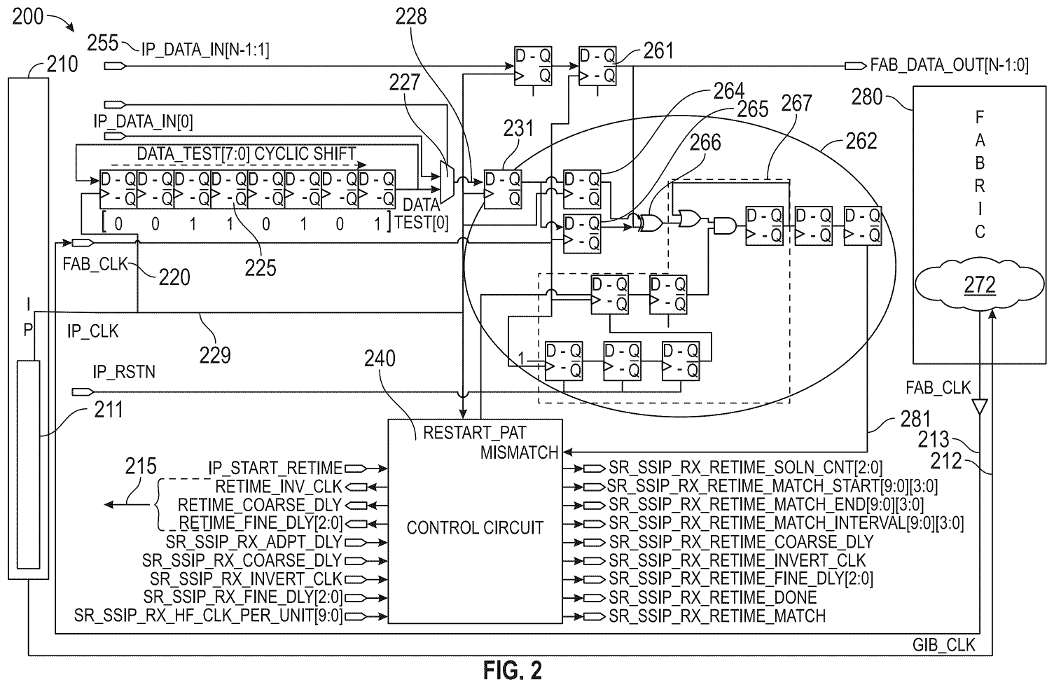

FIG. 2 illustrates one of various examples of a retiming circuit 200 to retime a clock signal in a receive path. Retiming circuit 200 includes circuits to align clock timing and to validate clock timing. A receive path may be a path for sending data from an IP block to fabric circuit 280. In one of various examples, an IP block may be an IP block within a field-programmable gate array (FPGA) device, and the fabric circuit 280 may be logic circuitry within the FPGA portion of that device.

IP block 210 may include one or more IP circuits. In the example illustrated in FIG. 2, IP block 210 may include delay circuit 211. In some examples, delay circuit 211 may be one of various examples of delay circuit 100 as described and illustrated in reference to FIG. 1.

A first clock, gib_clk 212, provides a source clock for examples of the present disclosure. Delay circuit 211 may generate a second clock, ip_clk 229, by applying a controlled amount of delay to gib_clk 212. Cloud 272 represents delay of the gib_clk 212 generated within the circuitry of fabric 280. Gib_clk 212 may represent a near end of a clock tree, and fab_clk 213 may represent a far end of a clock tree.

Fab_clk 213 may be coupled to port 220 and may clock data from data bus IP_DATA_IN[N−1:0] 255 (via an intermediate FF clocked by ip_clk 229) at capture flip-flop (FF) 261. In some examples, one bit of data input 255 is routed through a validation circuit to allow runtime validation of the settings for delay circuit 211, in other words ongoing validation when the circuit is in an operational mode.

Ip_clk 229 may be input to retiming circuit 200. Ip_clk may also be termed an IP clock. Ip_clk 229 may clock shift register 225 to provide a series of synthetic test bits for optional use by the validation circuit. Multiplexer 227 may select one of its inputs to be provided to its output 228. Output 228 may be clocked by ip_clk 229 at flip flop (FF) 231 and the output of FF 231 may be input to retiming circuit 262. In some examples, multiplexer 227 may select the synthetic test bits during a calibration mode to provide a steady stream of data as the control circuit 240 sequences through delay values and observes whether data sampled under the delayed clock generated by delay circuit 211 matches data sampled under ip_clk 229.

Fab_clk 213 may be input to retiming circuit 262. Fab_clk may also be termed fabric clock. The output of capture FF 261 may be input to validation circuit 262.

Validation circuit 262 may compute mismatch signal 281. Output 281 may represent a relationship between ip_clk 229 and fab_clk 213. Output 281 may represent a mismatch between ip_clk 229 and fab_clk 213. Output 281 may be input to control circuit 240. Validation circuit 262 may include FF 264, which is clocked with ip_clk 229, and FF 265, which is clocked with fab_clk 213. The outputs of FF 264 and FF 265 are compared by XOR 266 to identify a difference in value. In this example, the output of XOR 266 is fed through resettable circuit 267 that will output a mismatch signal on output 281 once a difference is identified by XOR 266 and will continue to output that mismatch signal until reset by control circuit 240. In other words, if any bit of the test sequence pattern captured by the FF 264 and FF 265 does not match, the mismatch signal will be raised for the duration of the test sequence in these examples. In some examples, validation circuit 262 may validate the timing during an operation mode. Multiplexer 227 may select live data from one of the lines of data input 255 to feed to FF 231. In an operation mode, validation circuit 262 may output a mismatch signal on output 281 until reset by control circuit 240. A timing mismatch may occur after calibration if, for example, the temperature of the device has changed or if other environmental conditions have changed.

Control circuit 240 may generate delay control outputs 215 to delay circuit 211 to change the timing of delay gib_clk 212, i.e., to increase, or decrease, the amount of delay provided by delay circuit 211. In some examples, delay control outputs 215 may include a clock inverter output to delay the clock by one half period, a coarse delay output, and a fine delay output. Control circuit 240 may also generate a signal to restart the test pattern and reset resettable memory circuit 267 to initiate a new test window during a calibration mode or resume active testing during an operation mode. Control circuit 240 may include a state machine to calibrate the amount of delay provided by delay circuit 211 during a calibration mode. In the calibration mode, control circuit 240 may check for a mismatch (via mismatch signal 281) using a test sequence over a range of delay values. Control circuit 240 may then note the lowest and highest delay values that result in no mismatch. Control circuit 240 may then set a delay value for an operating mode at a midpoint between the lowest and highest delay values that result in no mismatch. In some examples, control circuit 240 may assign a numeric value to each component of delay (inversion, coarse delay, and fine delay) and may average the numeric proxy for lowest and highest delay values that result in no mismatch. In some examples, the numeric values directly translate to a selection of component delay values (inversion, coarse delay, and fine delay) and the numeric average may be selected as the initial delay for an operating mode. In some examples, the numeric values roughly translate to an amount of time. For example, the inversion delay may be half a clock cycle, the coarse delay may be 1000 ps, and the fine delay increments may be 125 ps. The calculated average may not align with an actual combination of delay components and control circuit 240 may select the set of component delay values nearest to the calculated average. In some examples, the fastest fabric clock period supported is 2000 ps and the fabric clock insertion delay may be between 500 ps and 2500 ps. In some examples, the targeted clock period ranges from 2000 ps to 80 ns with a duty cycle of approximately 40-50%. In some examples, the final gap between clock periods may be between 3500 ps and 4000 ps.

In some examples, after a reset, control circuit 240 waits for a signal on ip_start_retime to begin the calibration process, which will determine and set the insertion delay amount for the operation of the device. During calibration, control circuit 240 may cycle through each delay option to identify the start, end, and width of the solution window. At each delay option, a pattern of test data may be sequentially set as the data value to be loaded into FF 264 and FF 265 and the outputs of those two flip flops compared. This comparison may be performed on data_test[7:0] or on one bit (one line) of data bus ip_data_in 255. In some examples, an 8-bit sequence is tested (e.g., “00110101”). In other examples, a 16-bit sequence is tested. In still other examples, a test sequence of a multiple of 8, may be used. In some examples, the signals listed in TABLE 1 may be input to or output by control logic 340.

TABLE 1

| signal name | Width | R/W | Default | Definition |
|---|---|---|---|---|
| sr_rx_adpt_dly/ | 1 | R/W | 1 | 0: Use register defined delays |
| sr_tx_adpt_dly | | | | 1: Use training pattern |
| sr_rx_use_test_pat/ | 1 | R/W | 0 | 1: Use hard coded test pattern, |
| sr_tx_use_test_pat | | | | 0: Use input data bit 0 (ip_data_in[0]/ |
| | | | | fab_data_in[0]) as test pattern |
| sr_rx_retime_fine_dly/ | 3 | RO | 0 | Retiming result for Fine delay control |
| sr_tx_retime_fine_dly | | | | from register map. 0: no delay 1-7: |
| | | | | delay added with 125 ps intervals |
| sr_rx_retime_coarse_dly/ | 1 | RO | 0 | Retiming result for fixed coarse |
| sr_tx_retime_coarse_dly | | | | delay 1: Using coarse delay. 0: No |
| | | | | coarse delay |
| sr_rx_retime_inv_clk/ | 1 | RO | 0 | Retiming result for inverted clock |
| sr_tx_retime_inv_clk | | | | 1: Inverted ip_clk. 0: No inversion |
| retime_fine_dly/ | 3 | RO | 0 | This is calibration logic output to |
| | | | | the delay macro for Fine delay control |
| | | | | from register map. 0: no delay 1-7: |
| | | | | delay added with 125 ps intervals |
| retime_coarse_dly | 1 | RO | 0 | This is calibration logic output to the |
| | | | | delay macro for fixed coarse delay 1: |
| | | | | Using coarse delay. 0: No coarse delay |
| retime_inv_clk | 1 | RO | 0 | This is calibration logic output to |
| | | | | the delay macro for inverted clock |
| | | | | 1: Inverted ip_clk. 0: No inversion |
| sr_rx_retime_done/ | 1 | RO | 0 | 1: Completed calibrating the |
| sr_tx_retime_done | | | | retiming. Level signal. |
| sr_rx_retime_match/ | 1 | RO | 0 | 1: retimed data to fabric matches the |
| sr_tx_retime_match | | | | data from ip. 0: Mismatch. Valid when |
| | | | | sr_tx_retime_done is high. Level signal. |
| sr_rx_retime_soln_cnt/ | 3 | RO | 0 | Valid solution count found in |
| sr_tx_retime_soln_cnt | | | | calibration. |
| sr_rx_retime_match_start/ | 5 × 2 | RO | −1 | Start of the 2 best solutions interval |
| sr_tx_retime_match_start | | | | encoded in 5 bits. If there is an inverted |
| | | | | solution it will be provided instead of |
| | | | | the second best solution. |
| | | | | Encoding: |
| | | | | [4]: 1: invert, 0: do not invert |
| | | | | [3]: 1: coarse delay 0: no coarse delay |
| | | | | [2:0]: number of fine delays added. |
| sr_rx_retime_match_end/ | 5 × 2 | RO | −1 | End of the 2 best solutions interval |
| sr_tx_retime_match_end | | | | encoded in 5 bits. If there is an inverted |
| | | | | solution it will be provided instead of |
| | | | | the second best solution. |
| | | | | Encoding: |
| | | | | [4]: 1: invert, 0: do not invert |
| | | | | [3]: 1: coarse delay 0: no coarse delay |
| | | | | [2:0]: number of fine delays added. |

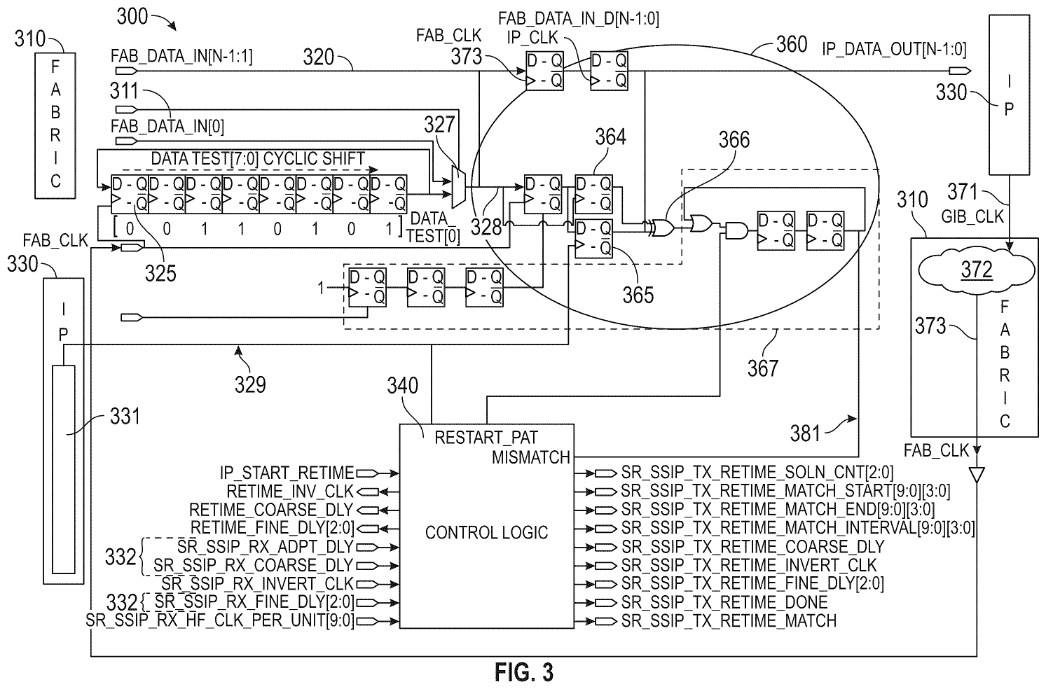

FIG. 3 illustrates one of various examples of a retiming circuit 300 for retiming a clock signal in a transmit path. A transmit path may be defined as a path for sending data from a fabric circuit to an IP block. In one of various examples, an IP block may be an IP block within a field-programmable gate array (FPGA), and the fabric circuit 310 may be logic circuitry within an FPGA.

In some examples, one bit of input data 311 may be routed through multiplexer 327 during an operating mode to be returned to bus 320 and fed into input 328 of validation circuit 360. In a calibration mode, selector 327 may rout data from test sequence generator 325 to input 328.

IP block 370 may generate clock signal 371. Clock signal 371 may also be termed gib_clk. Gib_clk 371 may be input to logic cloud 372, which may represent a series of sequential circuits clocked by gib_clk 371 or may represent other combinational or sequential circuits. Fab_clk 373 may be output from logic cloud 372 with a delay generated by delay circuit 331 in IP block 330 based on delay control outputs 332. Delay circuit 331 may be one of various examples of delay circuit 100 as described and illustrated in reference to FIG. 1. Gib_clk 371 may represent a near end of a clock tree, and fab_clk 373 may represent a far end of a clock tree.

Validation circuit 360 may compute output 381. Output 381 may represent a relationship between ip_clk 329 and fab_clk 373. Output 381 may represent a mismatch between ip_clk 329 and fab_clk 373. Output 381 may be input to control circuit 340. Validation circuit 360 may include FF 365, which is clocked with ip_clk 329, and FF 364, which is clocked with fab_clk 373. The outputs of FF 364 and FF 365 are compared by XOR 366 to identify a difference in value. In this example, the output of XOR 366 is fed through resettable memory circuit 367 that will output a mismatch signal on output 381 once a difference is identified by XOR 366 and will continue to output that mismatch signal until reset by control circuit 340. In other words, if any bit of the test sequence pattern captured by the FF 364 and FF 365 does not match, the mismatch signal will be raised for the duration of the test sequence in these examples. In some examples, validation circuit 360 may validate the timing during an operation mode. Selector 327, which may be a multiplexer, may select live data from a line of data input from bus 320. In an operation mode, validation circuit 360 may output a mismatch signal on output 381 until reset by control circuit 340. A timing mismatch may occur after calibration if, for example, the temperature of the device has changed or if other environmental conditions have changed.

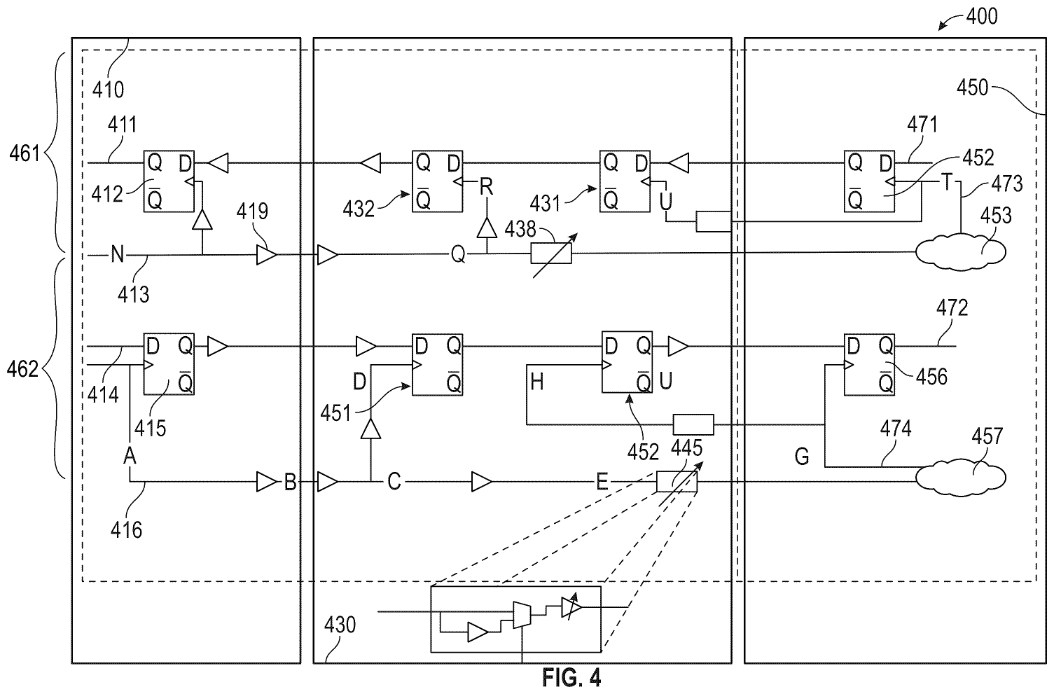

FIG. 4 one of various examples of a retiming circuit. System 400 includes transmit data path 461 carrying data from FPGA fabric 450 to IP circuit 410 and receive data path 462 in the reverse direction. System 400 includes retiming circuit 430.

IP circuit 410 may latch transmit data by clocking transmit FF 412 with clock 413 and propagating transmit data on line 411. IP circuit 410 may latch receive data from line 414 at FF 415 with clock 416. FPGA fabric 450 may latch transmit data on line 471 at latch 452 with clock 473. The output of latch 452 may feed pipeline FF 431 of retiming circuit 430. FPGA fabric 450 may latch receive data from pathway FF 452 (of retiming circuit 430) at latch 456 with clock 474.

Retiming circuit 430 may latch data along transmit path 461 using an originating clock signal and a delayed clock signal to retime the transmit signal for consumption by IP block 410. The transmit signal may be received from latch 452 at pipeline FF 431 and clocked by clock 473. Retiming circuit 430 may include adjustable delay circuit 438 for delaying clock 413 to retime clock 473. Insertion delay 453 represents an unpredictable insertion delay generated by circuitry within FPGA fabric 450.

Similarly, retiming circuit 430 may latch data along receive path 462 using an originating clock signal and a delayed clock signal to retime the receive signal for consumption by FPGA fabric 450. Retiming circuit 430 may also include adjustable delay circuit 445 to retime clock 416 to feed to FF 456 and capture FF 452. Insertion delay 457 represents an unpredictable insertion delay generated by circuitry within FPGA fabric 450.

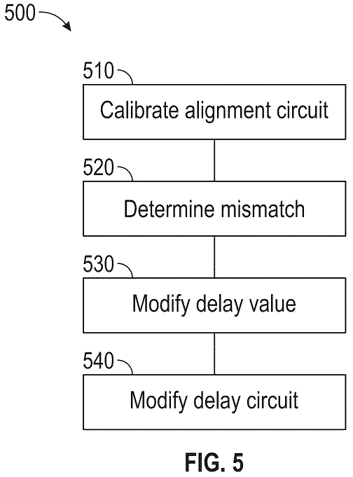

FIG. 5 illustrates method 500 for retiming signals.

At operation 510, during calibration, a calibration mode may calibrate an retiming circuit. As discussed above, the calibration may sequentially test a series of timing delays to determine at least one delay value that results in no mismatch on a data path between the IP block and the fabric. In some examples, the calibration mode determines a minimum delay value that results in no data mismatch and a maximum delay value that results in no data mismatch. A midpoint between the determined minimum and maximum delay values may be selected. This process may be repeated for each data path (e.g., the transmit and receive data paths). In some examples, the calibration mode may begin with the least delay and sequentially increase delay to determine the minimum and maximum delay values. In some examples, the calibration mode may begin with the maximum delay and sequentially decrease delay. In some examples, the calibration process may test possible delay values in a nonsequential manner to accelerate the search process.

At operation 520, during normal operation, the retiming circuit may compute a mismatch signal based on a relationship between an IP clock and a fabric clock. During normal operation, the retiming circuit may signal to the control circuit if a mismatch occurs. In some examples, this mismatch signal may trigger a return to the calibration mode. In some examples, the control circuit may first retest at the previously determined minimum and maximum delay values to determine whether the currently selected delay value is too low or two high in order to accelerate a search for a new minimum and a new maximum delay value.

At operation 530, a control circuit may modify a delay value in response to the mismatch signal. In some examples, the control circuit may start a test cycle to determine a new minimum delay value that does not result in a mismatch signal. In some examples, the control circuit may adjust the delay value to the new minimum delay value. In some examples, the control circuit may adjust the delay value to the new minimum delay value plus a predetermined data skew value. In some examples, the control circuit may adjust the delay value to half the distance between the new minimum delay value and the maximum delay valued.

At operation 540, a delay circuit may receive the at least one retimer control signal and may modify a delay on at least one of the IP clock and the fabric clock based on the at least one retimer control signal.

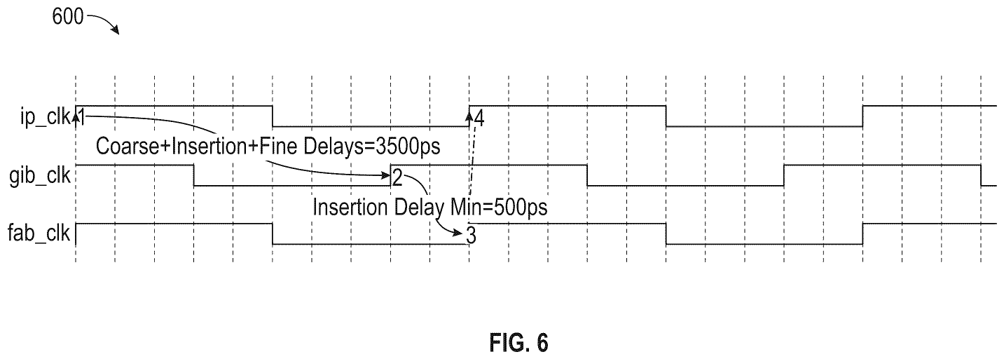

FIG. 6 illustrates one of various examples of a relationship between an IP clock, a fabric clock and a gib clock.

Within an ASIC design, there are cases where a block generates data with a clock-forwarded architecture. Normally, this is a simple interface where the delay to external blocks on the clock signal is similar to those on the data paths. In some cases, however, due to the placement of blocks in the design, the clock routing delays between an IP that generates its own clock and the IP data path can be very high, with a maximum amount of 1.25 times the fastest clock period supported by the overall circuit. In addition, these delays can be variable depending on process, voltage, and temperature. This disclosure addresses this issue by accomplishing the following:

Modifying the delay on the clock being supplied to the fabric on a part-by-part basis (thus allowing for process changes).

Determining a delay that provides an improved margin, such as the largest margin, to allow for normal variations in temperature and voltage.

Allowing for a simple integration with a traditional fly-wheel-FIFO.

Allowing for a self-checking feature which can verify that the existing clock delays still work within the system.

Allowing for a self-testing feature which can be used to test the clock delay path in cases where there are no data transitions on the data path.

To accomplish this, a control circuit may be added to the data path that allows for control of a clock delay circuit. In some examples, an IP clock will be delayed by a controlled amount to generate a gib_clk. The gib_clk may then be further delayed to generate an FPGA fabric clock. The delay amount may be kept stable after a calibration process. In some examples, register settings may be provided to allow user override of the delay amount.

In some examples, all instances of retiming modules need to be reset simultaneously, since the output gib_clk will be shared by fabric.

The system forwards a clock to the FPGA fabric and addresses the following:
(1) Modifying the delay on the clock being supplied to the fabric on a part-by-part basis (thus allowing for process changes)
(2) Determining a delay that provides an improved margin, e.g., the largest margin, to allow for normal variations in temperature and voltage.
(3) Allowing for a simple integration with a traditional fly-wheel-FIFO
(4) Allowing for a self-checking feature which can verify that the existing clock delays still work within the system
(5) Allowing for a self-testing feature which can be used to test the clock delay path in cases where there are no data transitions on the data path.

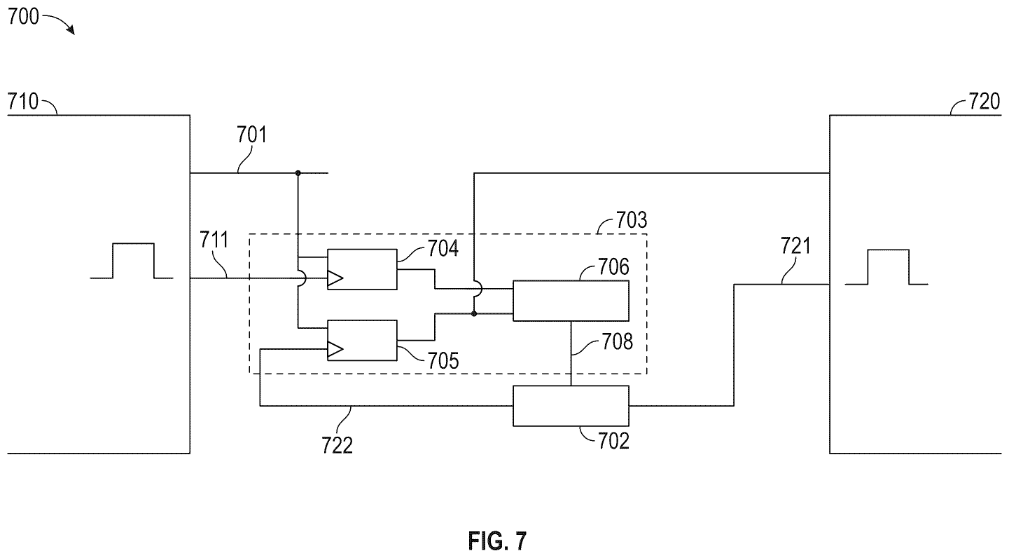

FIG. 7 illustrates one of various examples of a device with an retiming circuit and a validation circuit. Device 700 may be an integrated circuit including a first portion operating synchronously with a first clock 711. Device 700 may include a second portion 720 operating synchronously with a second clock 721. First portion 710 and second portion 720 may be coupled via data line 701. Retiming circuit 702 may be provided to introduce a delay of a delay value to second clock 721 to generate delayed clock 722. Device 700 may include validation circuit 703 to receive a data value arriving from first portion 710 along data line 701. Data line 701 may serve as a data input to validation circuit 703. The validation circuit 703 may capture at first sample memory 704 a first sample of the data value sampled with the first clock and may capture at second sample memory 705 a second sample of the data value sampled with delayed clock 722. Validation circuit 703 may compare the first sample with the second sample at comparing circuit 706 to generate mismatch signal 708. Comparing circuit 706 may be an XOR gate. Retiming circuit 702 may adjust the delay value responsive to the mismatch signal 708.

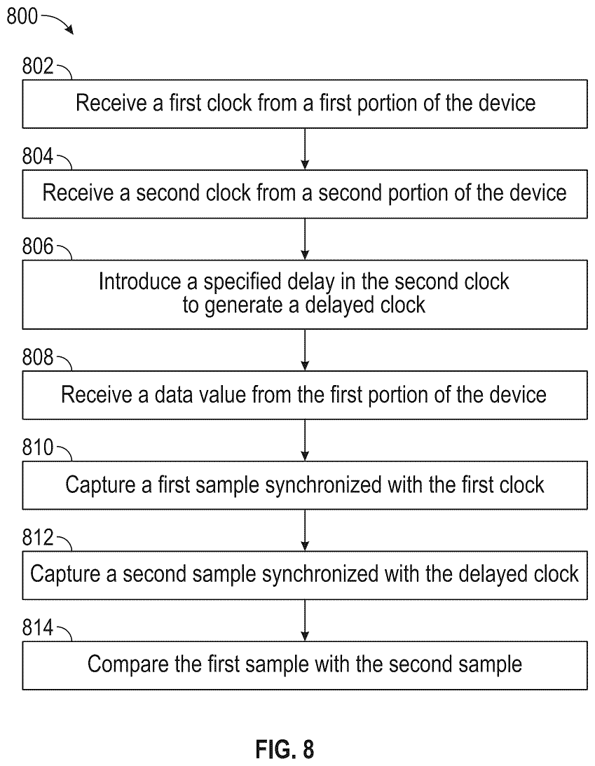

FIG. 8 illustrates one of various examples of method 800 for validating a delay in an integrated circuit device. At block 802, a device receives a first clock from a first portion of the device. At block 804, the device receives a second clock from a second portion of the device. At block 806, the device introduces a specified delay in the second clock to generate a delayed clock. In some examples, the delay amount may be specified by a stored value. In some examples, the delay amount may be determined by iteratively increasing the delay amount as discussed above in this disclosure. At block 808, a validation circuit receives a data value from the first portion of the device. At block 810, the validation circuit captures a first sample of the data value sampled with the first clock. At block 812, the validation circuit captures a second sample of the data value sampled with the delayed clock. At block 814, the validation circuit compares the first sample with the second sample to determine whether they match.

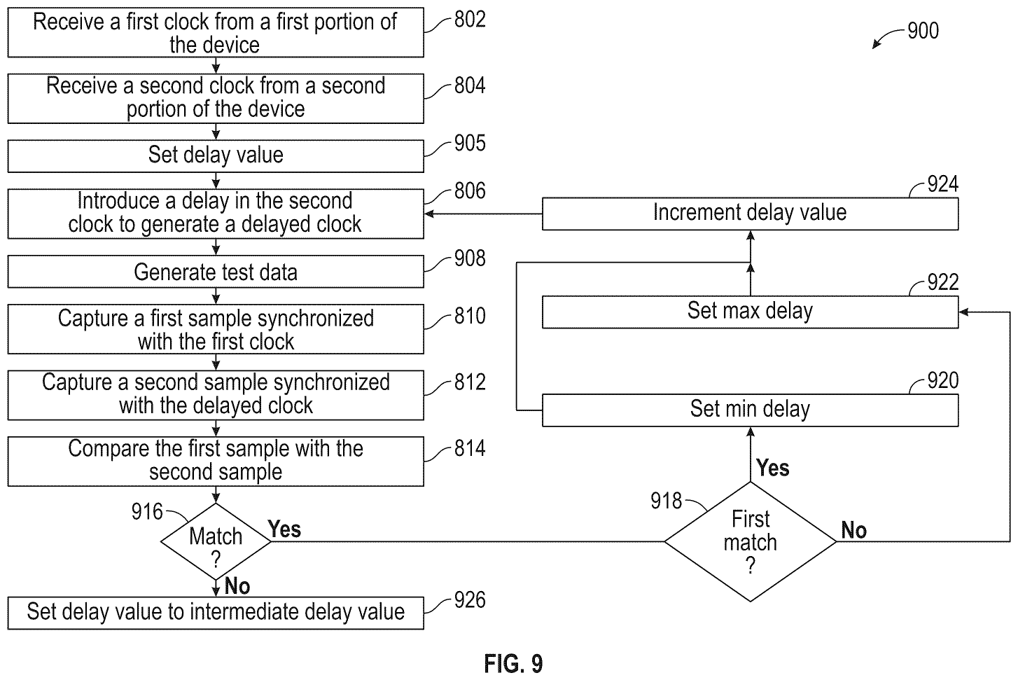

FIG. 9 illustrates one of various examples of method 900 for adjusting a delay in an integrated circuit device. At block 802, a device receives a first clock from a first portion of the device. At block 804, the device receives a second clock from a second portion of the device. At block 905, an retiming circuit sets a delay value. At block 806, the device introduces the set delay of block 905 in the second clock to generate a delayed clock. At block 908, a validation circuit generates a test data value. At block 810, the validation circuit captures a first sample of the test data value sampled with the first clock. At block 812, the validation circuit captures a second sample of the test data value sampled with the delayed clock. At block 814, the validation circuit compares the first sample with the second sample. At block 916, the validation circuit determines whether the first sample and second sample match. If the samples do not match, at block 926, the delay value is set to an intermediate delay value between the minimum and maximum values captured at blocks 920 and 922, respectively. In some examples, the min delay and max delay may be initialized to invalid or inconsistent values as part of the algorithm so as to allow the circuit to determine that no match occurred. In other examples, block 926 may first check whether any match occurred before accessing the min delay or max delay values. If the samples do match, at block 918, the method determines whether this is the first match of the method. If it is the first match, at block 920, the current delay value is set as the minimum delay value and the method advances to block 924. If not, at block 922, the current delay value is set as the maximum delay value. At block 924, the delay value is incremented and the method returns to block 806.

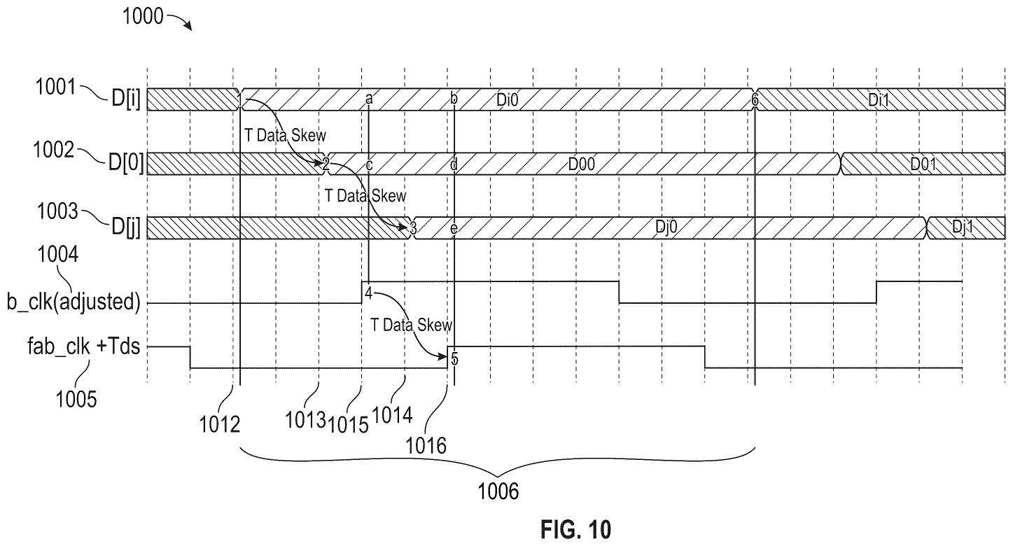

FIG. 10 is a timing diagram illustrating timing of various data lines according to certain examples of the present disclosure. Timing diagram 1000 shows the time values are valid on each of three data lines: line 1001 is D[i], line 1002 is D[0], and line 1003 is D[j]. Data line D[0] represents the lowest bit of a data bus. D[i] represents the fastest data path and D[j] represents the slowest data path. Timing diagram also includes fab_clk (adjusted) 1004, representing a fabric clock delayed sufficiently to capture data on line D[0]. Fab_clk_+T_{ds} 1005 represents the delayed fabric clock further delayed by the worst-case data skew time, T_{ds}. The clock period 1006 is illustrated below the diagram for reference.

In some examples, the retiming module is sampling only data line D[0], which may be ip_data_in[0] or fab_data_in[0] of the scenarios discussed above. The maximum data skew within the data bus is determined or estimated to be T_{ds}. It may not be certain which signals on data bus D[N−1:0] propagate the fastest or the slowest. For example, it is possible that D[0] is the fastest signal of the bus and in comparison some other signal, say D[i], is the slowest signal. In this scenario, D[i] is valid at time 1012 and D[0] is valid at time 1013. In this scenario, sampling according to fab_clk (adjusted) 1004 at time 1015 would successfully capture data from both the slowest and fastest signals, 1001 and 1002, respectively. Alternatively, it is possible that D[0] is the slowest signal and another signal, say D[j], is the fastest signal. In this alternate scenario, D[j] is not valid until time 1014 and sampling at time 1015 would capture D[0] but not D[j]. Therefore, it is prudent to further delay the clock by T_{ds}, and sample according to fab_clk+T_{ds} 1005 to ensure all data values on bus D[N−1:0] are validly captured.

In some examples, TABLE 2 includes data collected from an analysis scanning the range of available delay by clock period using the above-described techniques. In this analysis, seven levels of fine delay (125 ps each) were provided in addition to a 1000 ps coarse delay. The clock duty cycle was 0.4 and the minimum clock insertion time was 500 ps. TABLE 2 includes clock periods ranging from 2000 ps to 80000 ps. TABLE 2 shows the range of fine delay values, the range of delay values include coarse delay plus fine delay, the range of delay values including inversion delay plus fine delay, the range of delay values including coarse delay plus inversion plus fine delay. The last column represents the amount of gap in coverage of the delay values. There is a final gap between clock periods 3500-4000 ps that is uncovered. Block level tests show that a matching insertion delay solution was found in the delay range before those gaps.

TABLE 2

| | Fine delay | | | | | | Coarse delay + | | |
|---|---|---|---|---|---|---|---|---|---|
| Clk | range | | Coarse delay + | | Inversion delay + | | inversion + fine | | Final |
| period | (in 7 steps) | | Fine delay | | fine delay | | tune range | | Gap |
| 2000 | 0 | 875 | 1000 | 1875 | 800 | 1675 | 2000 | 2875 | 0 |
| 2100 | 0 | 875 | 1000 | 1875 | 840 | 1715 | 2000 | 2875 | 0 |
| 2200 | 0 | 875 | 1000 | 1875 | 880 | 1755 | 2000 | 2875 | 0 |
| 2400 | 0 | 875 | 1000 | 1875 | 960 | 1835 | 2000 | 2875 | 0 |
| 2600 | 0 | 875 | 1000 | 1875 | 1040 | 1915 | 2000 | 2875 | 0 |
| 2800 | 0 | 875 | 1000 | 1875 | 1120 | 1995 | 2000 | 2875 | 0 |
| 3000 | 0 | 875 | 1000 | 1875 | 1200 | 2075 | 2000 | 2875 | 125 |
| 3100 | 0 | 875 | 1000 | 1875 | 1240 | 2115 | 2000 | 2875 | 225 |
| 3200 | 0 | 875 | 1000 | 1875 | 1280 | 2155 | 2000 | 2875 | 325 |
| 3300 | 0 | 875 | 1000 | 1875 | 1320 | 2195 | 2000 | 2875 | 425 |
| 3400 | 0 | 875 | 1000 | 1875 | 1360 | 2235 | 2000 | 2875 | 525 |
| 3500 | 0 | 875 | 1000 | 1875 | 1400 | 2275 | 2000 | 2875 | 625 |
| 3600 | 0 | 875 | 1000 | 1875 | 1440 | 2315 | 2000 | 2875 | 725 |
| 3700 | 0 | 875 | 1000 | 1875 | 1480 | 2355 | 2000 | 2875 | 825 |
| 3800 | 0 | 875 | 1000 | 1875 | 1520 | 2395 | 2000 | 2875 | 925 |
| 3900 | 0 | 875 | 1000 | 1875 | 1560 | 2435 | 2000 | 2875 | 1025 |
| 4000 | 0 | 875 | 1000 | 1875 | 1600 | 2475 | 2000 | 2875 | 1125 |
| 4100 | 0 | 875 | 1000 | 1875 | 1640 | 2475 | 2000 | 2875 | 1225 |
| 5000 | 0 | 875 | 1000 | 1875 | 2000 | 2475 | 2000 | 2875 | 2125 |
| 6000 | 0 | 875 | 1000 | 1875 | 2400 | 2475 | 2000 | 2875 | 3125 |
| 7000 | 0 | 875 | 1000 | 1875 | 2800 | 2475 | 2000 | 2875 | 4125 |
| 8000 | 0 | 875 | 1000 | 1875 | 3200 | 2475 | 2000 | 2875 | 5125 |
| 9000 | 0 | 875 | 1000 | 1875 | 3600 | 2475 | 2000 | 2875 | 6125 |
| 10000 | 0 | 875 | 1000 | 1875 | 4000 | 2475 | 2000 | 2875 | 7125 |
| 20000 | 0 | 875 | 1000 | 1875 | 8000 | 2475 | 2000 | 2875 | 17125 |
| 40000 | 0 | 875 | 1000 | 1875 | 16000 | 2475 | 2000 | 2875 | 37125 |
| 80000 | 0 | 875 | 1000 | 1875 | 32000 | 2475 | 2000 | 2875 | 77125 |
| 80000 | 0 | 875 | 1000 | 1875 | 32000 | 2475 | 2000 | 2875 | 77125 |

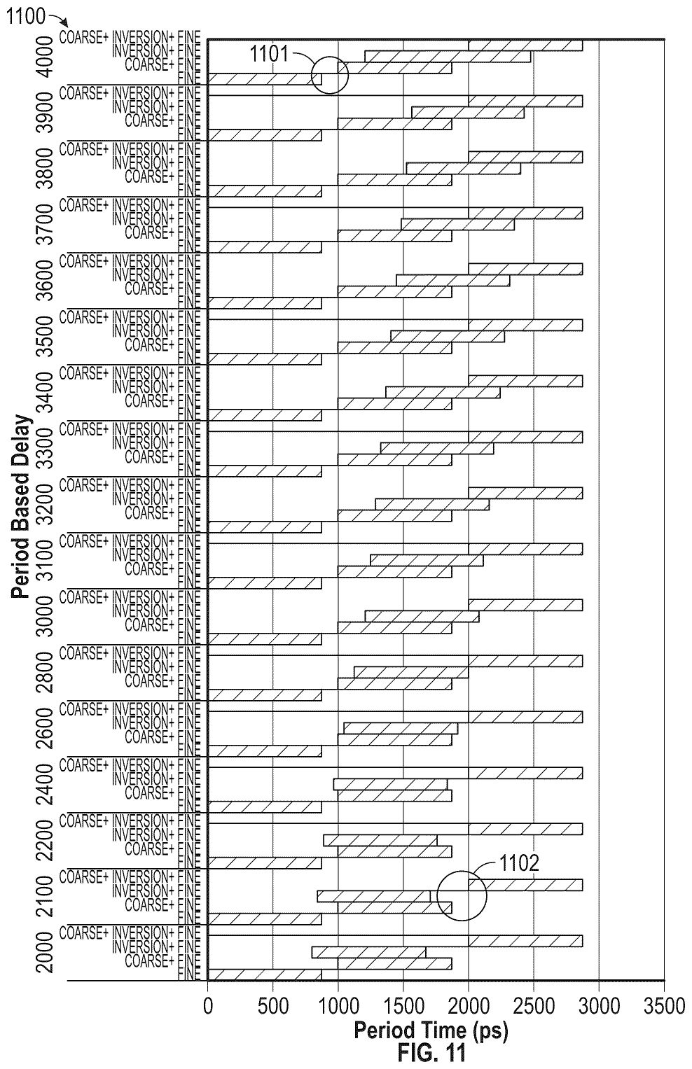

FIG. 11 illustrates delay coverage by clock period, according to certain examples of the present disclosure. This figure includes data collected from an analysis scanning the range of available delay by clock period using the above-described techniques. In this analysis, seven levels of fine delay (125 ps each) were provided in addition to a 1000 ps coarse delay. The clock duty cycle was 0.4 and the minimum clock insertion time was 500 ps. TABLE 2 includes clock periods ranging from 2000 ps to 4000 ps. The gaps in FIG. 11 are equal to 125 ps, which is one unit of fine delay. Therefore, coverage is good over a range of zero to approximately 2875 ps of the clock period.

TABLE 3 shows a static timing analysis (STA) for parallel instantiation of fine delay cells with no input delay and ideal clocks. The first column captures the cell name from a library of existing designs. The second column provides an instance ID used in the analysis. The next group of columns captures the setup delay in picoseconds and the final group captures the hold delay in picoseconds, all of which are captured for a range of voltage conditions. The cell named DLYCLK8S8_X2N_A7P5PP84TL_C18 operating at 0.99V (0.9V+10%) provides the minimum amount of hold delay. The minimum hold delay for each cell is considered, because additional fine delay can be accommodated but not a smaller delay. With additional fine delay, the total coverage area increases, but a smaller fine delay may result in uncovered gaps in clock insertion delay combinations. Targeting 1 fine delay at 125 ps requires a series of four DLYCLK8S8_X2N_A7P5PP84TL_C18 cells. And a course delay of 1000 ps requires a series of thirty two DLYCLK8S8_X2N_A7P5PP84TL_C18 cells.

TABLE 3

| | Instance | Setup delay in ps | | | Hold delay in ps | | |
|---|---|---|---|---|---|---|---|
| Cell name\Operating Condition | ID | 0.81 V | 0.72 V | 0.63 V | 0.99 V | 0.88 V | 0.77 V |
| DLYCLK8S2_X1N_A7P5PP84TL_C18 | DC1 | 20 | 24 | 34 | 10 | 12 | 12 |
| DLYCLK8S2_X2N_A7P5PP84TL_C18 | DC2 | 19 | 23 | 33 | 9 | 11 | 12 |
| DLYCLK8S4_X1N_A7P5PP84TL_C18 | DC3 | 35 | 42 | 59 | 17 | 21 | 23 |
| DLYCLK8S4_X2N_A7P5PP84TL_C18 | DC4 | 34 | 42 | 59 | 17 | 20 | 23 |
| DLYCLK8S6_X1N_A7P5PP84TL_C18 | DC5 | 50 | 60 | 84 | 24 | 30 | 33 |
| DLYCLK8S6_X2N_A7P5PP84TL_C18 | DC6 | 49 | 60 | 84 | 24 | 29 | 33 |
| DLYCLK8S8_X1N_A7P5PP84TL_C18 | DC7 | 61 | 78 | 109 | 31 | 39 | 43 |
| DLYCLK8S8_X2N_A7P5PP84TL_C18 | DC8 | 61 | 77 | 107 | 31 | 38 | 43 |
| BUFH_X2N_A7P5PP84TL_C18 | | 14 | 16 | 24 | 7 | 8 | 9 |
| INV_X4N_A7P5PP84TL_C18 pair | | 10 | 11 | 15 | 5 | 6 | 7 |

TABLE 4 shows an additional static timing analysis of the delay cells comparing the use of four DC8 cells in series versus three DC8 cells and one DC5 cell in series. The first combination ensures at least 125 ps fine delay over the range of voltages whereas the second combination results in substantially less than 125 ps at the highest voltage in the analysis.

When the longest path is selected, the STA measured values for the hold delay will be at 1750 ps at 0.99V as seen here. The longest path delay may vary 1.92 to 2.32 times depending on pressure, voltage, and temperature.

TABLE 4

| Accumulating 1 fine | | Total delay | | |
|---|---|---|---|---|
| delay = 125 ps | | 0.9 V | 0.8 V | 0.7 V |
| Combine hold: | (DC8) ×4 | 124 | 152 | 172 |
| Combine hold: | (DC8) ×3 + DC5 | 117 | 147 | 162 |

TABLE 5 shows additional STA measured values verses calculated values over a range of voltages. When the longest path is selected, the STA measured values for the hold delay will be at 1750 ps at 0.99V as seen here. The longest path delay may vary 1.92 to 2.32 times depending on pressure, voltage, and temperature.

TABLE 5

| | | Calculated | | | STA measured | | |
|---|---|---|---|---|---|---|---|
| Longest path: 1 coarse + | | values: | | | values: | | |
| 7 fine delays | | 0.9 V | 0.8 V | 0.7 V | 0.9 V | 0.8 V | 0.7 V |
| | target | 1875 | 1875 | 1875 | 1875 | 1875 | 1875 |
| setup delay for coarse + | max | 3660 | 4620 | 6420 | 3510 | 4185 | 5723 |
| fine delay | | | | | | | |
| hold delay for coarse + | min | 1860 | 2280 | 2580 | 1750 | 2183 | 2471 |
| fine delay | | | | | | | |
| | max/min | 1.97 | 2.03 | 2.49 | 2.01 | 1.92 | 2.32 |
| | ratio | | | | | | |

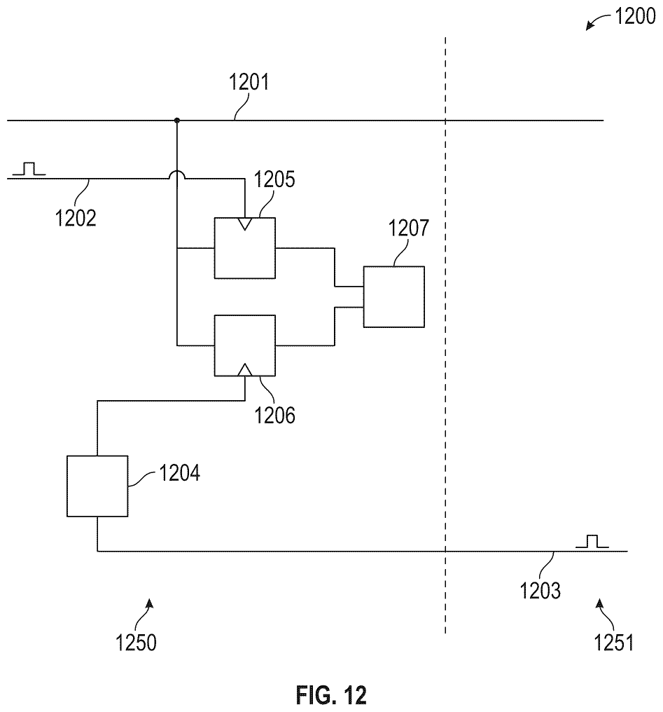

FIG. 12 illustrates one of various examples of a device. Device 1200 may include first portion 1250 in communication with second portion 1251 over data line 1201. A retiming circuit of the device receives first clock 1202 from first portion 1250 and second clock 1203 from second portion 1251. Delay circuit 1204 introduces delay into second clock 1203 to generate a delayed clock. A validation circuit receives a data value on data line 1201 and captures that data value at sample circuit 1205 when triggered by first clock 1202. The validation circuit also captures that data value at sample circuit 1206 when triggered by the delayed clock. The two sampled values feed into test circuit 1207 that determines whether they match.

Although examples have been described above, other variations and examples may be made from this disclosure without departing from the spirit and scope of these examples.

We claim:

1. A device comprising:
a first portion of the device in communication via a data line with a second portion of the device,
an retiming circuit to:
receive a first clock from the first portion of the device and a second clock from the second portion of the device; and
introduce a delay value in the second clock to generate a delayed clock; and
a validation circuit to:
receive a data value arriving at the first portion of the device;
capture a first sample of the data value sampled with the first clock;
capture a second sample of the data value sampled with the delayed clock; and
compare the first sample with the second sample.

2. The device of claim 1, wherein in a calibration mode, the validation circuit is to:
identify a minimum delay value wherein the validation circuit determines no mismatch based on the comparison of the first sample with the second sample;
identify a maximum delay value wherein the validation circuit determines no mismatch based on the comparison of the first sample with the second sample; and
select an intermediate delay value between the minimum delay value and the maximum delay value.

3. The device of claim 1, wherein the intermediate delay value is centered between the minimum delay value and the maximum delay value.

4. The device of claim 1, wherein the intermediate delay value is offset by a configurable offset setting from the center between the minimum delay value and the maximum delay value.

5. The device of claim 1, wherein the validation circuit is to, in an operational mode:
determine a mismatch based on the comparison of the first sample with the second sample;
modify the delay value;
receive a subsequent data value arriving at the first portion of the device;
capture a first sample of the subsequent data value sampled with the first clock;
capture a second sample of the subsequent data value sampled with the delayed clock; and
determine no mismatch based on a comparison of the first sample of the subsequent data value and the second sample of the subsequent data value.

6. The device of claim 1, wherein the validation circuit is to, in a calibration mode, generate a test pattern to sequentially set the data value arriving at the first portion of the device.

7. The device of claim 1, wherein the validation circuit is to, in a calibration mode, select a line of a data bus between the first portion of the device and the second portion of the device to obtain the data value arriving at the first portion of the device.

8. The device of claim 1, wherein in a calibration mode, the validation circuit is to:
set the delay to a next delay value;
set a subsequent data value arriving at the first portion of the device;
capture a first sample of the subsequent data value sampled with the first clock;
capture a second sample of the subsequent data value sampled with the delayed clock; and
determine no mismatch based on a comparison of the first sample of the subsequent data value and the second sample of the subsequent data value;
add a data skew amount of time to the delay; and
exit the calibration mode.

9. The device of claim 1, wherein the delay value specifics a specific delay circuit path.

10. A device comprising:
a first clock;
a retiming circuit to generate a delayed clock from a second clock; and
a validation circuit including:
a data input;
a first sample memory coupled to the data input, the first sample memory to sample the data input, the first sample memory to sample the data input with the first clock;
a second sample memory coupled to the data input, the second sample memory to sample the data input with the delayed clock; and
a comparing circuit to compare an output of the first sample memory with an output of the second sample memory.

11. The device of claim 10, wherein the validation circuit is, in a calibration mode, to generate a test pattern to sequentially set a data value on the data input.

12. The device of claim 10, wherein the validation circuit is to, in a calibration mode:
select a delay value by changing an input to a delay selection circuit within the retiming circuit;
set a subsequent data value on the data input;
receive the subsequent data value at the first sample memory clocked with the first clock;
receive the subsequent data value at the second sample memory clocked with the delayed clock;
determine no mismatch by comparing the output of the first sample memory with the output of the second sample memory; and
exit the calibration mode.

13. The device of claim 10, wherein the delay selection circuit selects a specific delay circuit path comprising at least one of an inverter, a coarse delay component, and a fine delay component.

14. The device of claim 12, wherein the validation circuit is to, in the calibration mode:
identify a minimum delay selection for which the validation circuit determines no mismatch by comparing the output of the first sample memory with the output of the second sample memory;
identify a maximum delay selection for which the validation circuit determines no mismatch by comparing the output of the first sample memory with the output of the second sample memory; and
select an intermediate delay value between the minimum delay value and the maximum delay value.

15. The device of claim 12, the validation circuit is to, in an operational mode:
determine a mismatch by comparing the output of the first sample memory with the output of the second sample memory; and
modify the input to the delay selection circuit to select a different amount of delay.

16. A method comprising:
receiving a first clock from a first portion of a semiconductor device and a second clock from a second portion of the semiconductor device;
introducing a delay in the second clock to generate a delayed clock delayed by a specified delay value;
receiving a data value arriving at the first portion of the semiconductor device;
capturing a first sample of the data value sampled with the first clock;
capturing a second sample of the data value sampled with the delayed clock; and
comparing the first sample with the second sample.

17. The method of claim 16, including generating a test pattern to sequentially set the data value arriving at the first portion of the semiconductor device.

18. The method of claim 16, including selecting a line of a data bus connecting the first portion of the semiconductor device to the second portion of the semiconductor device to obtain the data value arriving at the first portion of the semiconductor device.

19. The method of claim 16, including:
setting the specified delay value to a next delay value;
setting a new data value arriving at the first portion of the semiconductor device;
determining no mismatch by comparing a first sample of the new data value sampled with the first clock with a second sample of the new data value sampled with the delayed clock; and
exiting the calibration mode.

20. The method of claim 16, wherein the specified delay value specifies a specific delay circuit path.

21. The method of claim 16, including:
identifying a minimum delay value for which the captured first sample equals the captured second sample;
identifying a maximum delay value for which the captured first sample equals the captured second sample;
determining an intermediate delay value between the minimum delay value and the maximum delay value; and
setting the specified delay value to the intermediate delay value.

22. The method of claim 16, including:
determining a mismatch by comparing the captured first sample and the captured second sample;
modifying the specified delay value;
receiving a subsequent data value arriving at the first portion of the semiconductor device;
capturing a first sample of the subsequent data value sampled with the first clock;
capturing a second sample of the subsequent data value sampled with the delayed clock; and
determining no mismatch based on a comparison of the first sample of the subsequent data value and the second sample of the subsequent data value.
